(19) United States
(12) Patent Application Publication
(10) Pub. No.: US 2015/0108531 A1
(43) Pub. Date: Apr. 23, 2015

(54) METHOD OF PRODUCING A COMPONENT CARRIER, AN ELECTRONIC ARRANGEMENT AND A RADIATION ARRANGEMENT, AND COMPONENT CARRIER, ELECTRONIC ARRANGEMENT AND RADIATION ARRANGEMENT

(71) Applicant: OSRAM Opto Semiconductors GmbH, Regensburg (DE)

(72) Inventors: Thomas Schwarz, Regensburg (DE); Stefan Grötsch, Bad Abbach (DE); Michael Zitzlsperger, Regensberg (DE)

(73) Assignee: OSRAM Optp Semiconductors GmbH, Regensburg (DE)

(21) Appl. No.: 14/398,557

(22) PCT Filed: May 7, 2013
(86) PCT No.: PCT/EP2013/059445

§ 371 Date: Nov. 3, 2014

(30) Foreign Application Priority Data
May 7, 2012 (DE) 10 2012 207 519.4

(51) Int. Cl. H01L 33/62; H01L 33/64; H01L 21/48; H01L 23/495

(52) U.S. Cl. CPC H01L 33/62; H01L 23/49568; H01L 33/64; H01L 21/4828
USPC 257/99; 29/827; 257/666

(57) ABSTRACT

A method of producing a component carrier for an electronic component includes a lead frame section including an electrically conductive material, the lead frame section having a first contact section that forms a first electrical contact element, a second contact section that forms a second electrical contact element, and a reception region that receives the electronic component, at least the reception region and the second contact section being electrically conductively connected to one another, a thermally conductive and electrically insulating intermediate element that dissipates heat from the reception region and electrically insulates the reception region formed at least on an opposite side of the lead frame section from the reception region, and a thermal contact that thermally contacts the electronic component formed at least on a side of the intermediate element facing away from the reception region.

### TECHNICAL FIELD

This disclosure relates to a method of producing a component carrier for an electronic component, a method of producing a radiation arrangement and to the component carrier and/or the radiation arrangement.

### BACKGROUND

Requirements are often placed on component carriers, for example, housings for electronic components, for example, radiation arrangements, for example, LEDs, that the LEDs are simple to contact, that the heat generated in the LEDs during operation can be transported away rapidly and effectively, and that the overall radiation arrangement consisting of the LED and the component carrier is simple and economical to produce. In conventional component carriers, besides other concepts, two different construction concepts are known in particular for component carriers.

For example, it is known to form a carrier body from ceramic and provide this with electrical contacts which extend on the surface of the carrier body and partially through the carrier body. One of the electrical contacts may have such a large area that the electronic component can be placed on the electrical contact. An LED, for example, a thin-film LED and/or a vertical LED (emission direction and/or current conduction perpendicular to the layer structure), may be fastened to the electrical contact such that it is fixed on the electrical contact and, at the same time, electrical contacting is provided via the physical contact. A further contact of the LED may be contacted with the other electrical contact of the component carrier, for example, by a bond connection. The carrier body made of ceramic electrically insulates the electrical contact on which the electronic component is fastened, and dissipates heat from the electronic component. For further dissipation of heat from the component carrier, a metallization may be formed on the carrier body on an opposite side of the ceramic carrier body from the electronic component. The metallization may, for example, also be used to produce a solder connection.

The component carrier comprising the ceramic carrier body may be placed on a printed circuit board, for example, on an FR4 printed circuit board such that the carrier body lies between the electronic component and the printed circuit board. The electrical contacts extending through the ceramic carrier body connect to conductor tracks of the printed circuit board. Furthermore, the metallization connects to thermal lines which extend through the printed circuit board and can connectto a heat sink. The printed circuit board contributes to good, simple and economical contacting and cooling of the electronic component.

Alternatively, it is known to use an electrically conducting lead frame section, for example, comprising metal for the component carrier. This can be produced particularly simply and economically. For example, the lead frame section may be part of a lead frame and the component carrier may be produced in a component carrier assembly by processing all the lead frame sections of the lead frame in the assembly. If a vertical LED is now used as the electronic component, as described above, then the lead frame section electrically contacts the electronic component and an electrical connection is established between the electronic component and the heat sink. Since the electronic component and the heat sink should not be electrically coupled to one another in many applications, a metal-core printed circuit board is, for example, used to fasten the component carrier, the metal core of the printed circuit board being insulated from the electrical contacts of the printed circuit board by a dielectric layer. The metal core of the metal-core printed circuit board may be used as a heat sink, and/or an additional heat sink thermally coupled to the metal core may be provided. The dissipation of heat from the radiation arrangement comprising the component carrier and the LED to the heat sink takes place via the dielectric layer of the metal-core printed circuit board.

Alternatively, it is possible to use an electronic component, for example, a horizontal LED (emission direction and/or current conduction parallel to the layer structure) in which no electrical contact is established between the electronic component and the lead frame section merely by the fastening on the lead frame section. Both electrical contacts of the electronic component may then, for example, be established by bond connections. Furthermore, an FR4 printed circuit board may be used to connect the component carrier to the heat sink.

### SUMMARY

We provide a method of producing a component carrier for an electronic component including: a lead frame section including an electrically conductive material, the lead frame section having a first contact section that forms a first electrical contact element, a second contact section that forms a second electrical contact element, and a reception region that receives the electronic component, at least the reception region and the second contact section being electrically conductively connected to one another, a thermally conductive and electrically insulating intermediate element that dissipates heat from the reception region and electrically insulates the reception region formed at least on an opposite side of the lead frame section from the reception region, and a thermal contact that thermally contacts the electronic component formed at least on a side of the intermediate element facing away from the reception region.

We also provide a method of producing an electronic arrangement including producing a component carrier according to the method of claim 17, applying the electronic component onto the reception region, contacting a first electrical contact of the electronic component with the first contact element, and, contacting a second electrical contact of the electronic component with the second contact element.

We further provide a method of producing a component carrier for an electronic component including providing a lead frame section which comprises an electrically conductive material, the lead frame section having a first contact section that forms a first electrical contact element, a second contact section that forms a second electrical contact element, and a reception region that receives the electronic component, at least the reception region and the second contact section electrically conductively connected to one another, forming the first contact element and the second contact element from the lead frame section, the first contact element being physically separated from the second contact element, forming a thermally conductive and electrically insulating intermediate element that dissipates heat from the reception region and electrically insulates the reception region at least on an opposite side of the lead frame section from the reception region, embedding the first and the second contact element at least partially in a molding material, and forming a thermal contact that thermally contacts the electronic component at least on a side of the intermediate element facing away from the reception region.

We still further provide a component carrier that receives and contacts an electronic component including: a lead frame section having a first contact element that contacts a first electrode of the electronic component, having a second contact element that contacts a second electrode of the electronic component, and having a reception region that receives the electronic component, the reception region and the second contact element electrically conductively connected to one another, an intermediate element that electrically insulates the reception region and arranged on an opposite side of the lead frame section from the reception region, a thermal contact that thermally contacts the electronic component, the thermal contact being arranged on the intermediate element on a side of the intermediate element facing away from the reception region.

We yet further provide an electronic arrangement including the component carrier and the electronic component.

We furthermore provide radiation arrangement including the component carrier and the electronic component, wherein the electronic component is a radiation source.

### BRIEF DESCRIPTION OF THE DRAWINGS

FIG. 1 shows one example of electronic arrangements on a printed circuit board, and a heat sink.

FIG. 2 shows another example of electronic arrangements on a printed circuit board and/or heat sink.

FIG. 3 shows a preform of one example of a lead frame section.

FIG. 4 shows the lead frame section in a first state during a first example of a method of producing a component carrier.

FIG. 5 shows the lead frame section in a second state during the first example of the method of producing a component carrier.

FIG. 6 shows the lead frame section in a third state during the first example of the method of producing a component carrier.

FIG. 7 shows the lead frame section in a fourth state during the first example of the method of producing a component carrier.

FIG. 8 shows the lead frame section in a first state during a second example of the method of producing a component carrier.

FIG. 9 shows the lead frame section in a second state during the second example of the method of producing a component carrier.

FIG. 10 shows the lead frame section in a third state during the second example of the method of producing a component carrier.

FIG. 11 shows the lead frame section in a fourth state during the second example of the method of producing a component carrier.

FIG. 12 shows the lead frame section in a fifth state during the second example of the method of producing a component carrier.

FIG. 13 shows the lead frame section in a first state during a third example of the method of producing a component carrier.

FIG. 14 shows the lead frame section in a second state during the third example of the method of producing a component carrier.

FIG. 15 shows the lead frame section in a third state during the third example of the method of producing a component carrier.

FIG. 16 shows the lead frame section in a fourth state during the third example of the method of producing a component carrier.

FIG. 17 shows the lead frame section in a fifth state during the third example of the method of producing a component carrier.

FIG. 18 shows the lead frame section in a sixth state during the third example of the method of producing a component carrier.

FIG. 19 shows the lead frame section in a first state during a fourth example of the method of producing a component carrier.

FIG. 20 shows the lead frame section in a second state during the fourth example of the method of producing a component carrier.

FIG. 21 shows the lead frame section in a third state during the fourth example of the method of producing a component carrier.

FIG. 22 shows the lead frame section in a fourth state during the fourth example of the method of producing a component carrier.

FIG. 23 shows the lead frame section in a fifth state during the fourth example of the method of producing a component carrier.

FIG. 24 shows the lead frame section in a sixth state during the fourth example of the method of producing a component carrier.

FIG. 25 shows the lead frame section in a first state during a fifth example of the method of producing a component carrier.

FIG. 26 shows the lead frame section in a second state during the fifth example of the method of producing a component carrier.

FIG. 27 shows the lead frame section in a third state during the fifth example of the method of producing a component carrier.

FIG. 28 shows the lead frame section in a fourth state during the fifth example of the method of producing a component carrier.

FIG. 29 shows the lead frame section in a fifth state during the fifth example of the method of producing a component carrier.

### DETAILED DESCRIPTION

We provide a method of producing a component carrier, a method of producing an electronic arrangement and/or a method of producing a radiation arrangement which simply and economically make it possible to produce the component carrier, the electronic arrangement and the radiation arrangement and/or which allow good electrical and thermal coupling of an electronic component to a printed circuit board and/or a heat sink.

A component carrier, an electronic arrangement and/or a radiation arrangement can be produced simply and economically and/or which allow good electrical and thermal coupling of an electronic component to a printed circuit board and/or a heat sink in a simple and economical way.

We provide a method of producing a component carrier for an electronic component. A lead frame section which comprises an electrically conductive material is thus provided. The lead frame section furthermore has a first contact section to form a first electrical contact element, a second contact section to form a second electrical contact element, and a reception region to receive the electronic component. At least the reception region and the second contact section electrically conductively connect to one another. A thermally conductive and electrically insulating intermediate element to dissipate heat from the reception region and for electrical insulation of the reception region is formed at least on an opposite side of the lead frame section from the reception region. A thermal contact to thermally contact the electronic component is formed at least on a side of the intermediate element facing away from the reception region.

Provision of the lead frame section comprising the electrically conductive material, formation of the intermediate element close or next to the reception region and formation of the thermal contact on the intermediate element contribute to the possibility of producing the component carrier simply and economically, the possibility of heat generated during operation of the electronic component being dissipated rapidly and effectively, and the possibility of the component carrier being coupled simply and economically with good electrical and thermal coupling to a printed circuit board and/or a heat sink. Furthermore, the electronic arrangement can have very good behavior under alternating thermal loading since the material of the printed circuit board section can be adapted particularly well to the thermal expansion coefficient of the printed circuit board and/or of the heat sink. In this case, the printed circuit board may, for example, be an FR1, FR2, FR3, FR4, FR5, CEM1, CEM2, CEM3, CEM4 or CEM5 printed circuit board, for example, a through-contacted FR-4 printed circuit board. The component carrier may, for example, also be referred to as a housing, QFN housing or QFN carrier. The lead frame section may, for example, also be referred to as a QFN lead frame. The component carrier with the electronic component may also be referred to as an electronic part or an electronic arrangement. The electronic component is, for example, a semiconductor chip and/or a light-emitting or light-absorbing component.

The heat sink may, for example, comprise aluminum. The component carrier may, for example, be coupled to the heat sink via the printed circuit board or directly.

The component carrier may, for example, be used to receive an electronic component. The component carrier with the electronic component may be referred to as an electronic arrangement. Furthermore, the component carrier with the electronic component may be referred to as a radiation arrangement if the electronic component comprises a radiation source, for example, a light-emitting component.

The lead frame section comprises the electrically conductive material and/or may be formed from the electrically conductive material. The electrically conductive material comprises, for example, a metal, for example, copper, for example, CuW or CuMo, copper alloys, brass, nickel and/or iron, for example, FeNi and/or is formed therefrom. The lead frame section is part of a lead frame which comprises a plurality of lead frame sections connected to one another, in which case each of the lead frame sections may, for example, be formed to form one of the component carriers. In other words, the lead frame may extend over a plurality of component carriers, in which case the multiplicity of component carriers may be formed and/or produced simultaneously so that a component carrier assembly is produced. The lead frames and/or the lead frame sections may, for example, be formed flat which means, for example, that the lead frame or each of the lead frame sections has a relatively small thickness compared with its length and its width.

Processing the lead frame section and, therefore, production of the component carrier, may be representative of processing the lead frame and, therefore, representative of production of the component carrier assembly. In other words, all the lead frame sections of the lead frame may be simultaneously processed in the same working steps as described with reference to the one lead frame section. After production of the component carrier assembly, the individual component carriers may be separated from the component carrier assembly, inter alia by cutting through the connections of the lead frame sections to one another.

The first contact element is used to contact a first contact of the electronic component. The second contact element is used to contact a second contact of the electronic component. The first and the second contact section may, for example, be formed next to one another in which case the reception region may be formed between the two contact sections. For example, the reception region may be arranged in a reception section formed between the first and the second contact section.

The intermediate element has, for example, a thickness of 1 to 1000 μm, for example, 10 to 200 μm, for example, 20 to 80 μm. The intermediate element has, for example, a thermal conductivity of 0.1 to 100 W/mK, for example, 0.5 to 20 W/mK, for example, 1 to 5 W/mK. The intermediate element may, for example, be applied in an already structured form onto the lead frame section. For example, the material of the intermediate element may be applied by screen printing, template printing, spraying (jet printing) or by a dispersion method, or introduced in liquid form into a shaping intermediate region of the lead frame section. Alternatively, the intermediate element may be applied flat onto the lead frame section and then structured. For example, the intermediate element may be applied as an intermediate layer, for example, by printing, casting or lamination, and eroded, and thereby structured, for example, by laser ablation or etching or mechanically, for example, by milling or scratching.

The solderable thermal contact has, for example, a thickness of 0.1 to 100 μm, for example, 1 to 10 μm, for example, approximately 5 μm. The thermal contact has, for example, a high thermal conductivity, for example, 100 to 1000 W/mK, for example, 200 to 500 W/mK, for example, 250 to 400 W/mK. The thermal contact is, for example, formed such that it is contactable via a solder connection. The thermal contact comprises, for example, metal, for example, copper, titanium, gold, silver, nickel and/or palladium, for example, NiPdAu. The thermal contact may, for example, be applied flat in a contact layer and then structured, or may be applied in a structured form. The thermal contact may, for example, be formed and/or structured with the aid of a photolithographic process and/or an etching process, and/or the thermal contact may be applied by an electroplating process.

The intermediate element comprises, for example, a dielectric and/or, for example, an organic and/or inorganic material. For example, the dielectric comprises ceramic particles and/or a carrier compound comprising ceramic particles. For example, ceramic particles are embedded in the carrier compound. For example, the carrier compound comprises epoxy resin, silicone and/or acrylic resin. For example, the ceramic comprises aluminum oxide, quartz, aluminum nitride, boron nitride and/or silicon carbide.

The thermal contact may comprise a metal. For example, the thermal contact comprises copper or is formed therefrom.

The first contact element and the second contact element may be formed from the lead frame section, the first contact element being physically separated from the second contact element. The first and the second contact element may be formed and/or separated from one another before or after the application of the intermediate element. The reception region is, for example, also in physical contact with the second contact element after formation or separation of the two contact elements. For example, the reception region is formed on the same material piece as the second contact element. In other words, the reception region and the second contact element may be formed in one piece.

The first contact element may be physically separated from the second contact element with the aid of an etching process. This can contribute to simple formation of the contact elements.

An intermediate region that receives the intermediate element may be formed on the opposite side of the lead frame section from the reception region. The intermediate region is optionally formed before the application of the intermediate element and may be formed before, during or after formation and/or separation of the first and second contact element. The intermediate region may, for example, comprise a recess in the lead frame section, or the intermediate region may comprise a taper at which the lead frame section has a smaller thickness than on the first and/or second contact element.

The intermediate region may be formed in the same working step as the first and the second contact element. For example, the intermediate region may be formed in the same etching process as that in which the first and the second contact element are formed and/or separated from one another.

The intermediate element and/or the thermal contact may be formed in the same working step as the first and the second contact element. For example, an intermediate layer and/or a contact layer may initially be applied onto the lead frame section, and then the intermediate element may be formed from the intermediate layer, or the thermal contact may be formed from the contact layer, in the same etching process as that in which the two contact elements are produced.

The first and the second contact element may be embedded at least partially in a molding material. In this context, the fact that the first and the second contact element are embedded in a molding material means that the first and the second contact element are at least partially surrounded by the molding material, but that regions of the first and second contact element and/or of the reception region and/or of the intermediate region and/or of the thermal contact may also remain free of molding material. The molding material may, for example, be an encapsulation compound or an injection-molding compound. The molding material may, for example, comprise an inorganic material, for example, a composite material, for example, epoxy resin, and/or silicone, a silicone hybrid and/or a silicone-epoxide hybrid. The first and the second contact element may, for example, be embedded in the molding material before or after formation of the intermediate region. The first and the second contact element may, for example, be embedded in the molding material before or after formation of the intermediate element and/or before or after formation of the thermal contact. The molding material may, for example, be used to mechanically connect the first and the second electrical contact element to one another and electrically insulate them from one another. Furthermore, the molding material may be used to externally insulate the two electrical contacts at least partially.

The molding material may be used as the intermediate element. For example, the molding material and the intermediate element may be formed in one working step and/or formed from the same material. For example, the molding material may form the intermediate element. This can contribute to the intermediate element being formed particularly simply and economically.

The molding material may be shaped such that it has a reception recess in which the first contact element, the second contact element and/or the reception region are at least partially exposed. This contributes to the possibility of fastening and/or contacting the electronic component in a straightforward way on the component carrier.

A method of producing an electronic arrangement is provided, wherein a component carrier is produced, for example, according to the method explained above, and wherein the electronic component is applied onto the reception region of the component carrier. A first electrical contact of the electronic component is contacted with the first contact element and a second electrical contact of the electronic component is contacted with the second contact element. The first and/or the second electrical contact may, for example, be contacted by bonding with the corresponding first and/or second contact element. The electronic component is, for example, a light-emitting component, for example, an LED or an OLED, or a light-absorbing component, for example, a solar cell.

If the second electrical contact is formed on a side of the electronic component facing toward the reception region, for example, if the electronic component is a vertical LED, then the contacting of the second contact with the second contact element may be carried out by applying the electronic component onto the reception region and via the physical connection of the reception region to the second contact element.

A method of producing a radiation arrangement is provided, wherein an electronic arrangement is produced, for example, according to the method or methods explained above, a radiation source being used as the electronic component. The radiation source is, for example, a light-emitting component, for example, an OLED or an LED, for example, a thin-film LED and/or, for example, a horizontal or vertical LED.

A component carrier that receives and contacts an electronic component is provided. The component carrier comprises a lead frame section, an intermediate element and a thermal contact. The lead frame section has a first contact element, a second contact element and a reception region. The first contact element is used to contact a first electrode of the electronic component. The reception region is used to receive the electronic component. The second contact element is used to contact a second electrode of the electronic component. The reception region and the second contact element electrically conductively connect to one another. The intermediate element is used to electrically insulate the reception region and dissipate heat from the reception region, and arranged on an opposite side of the lead frame section from the reception region. The thermal contact is used to thermally contact the electronic component, for example, via the intermediate element and the reception region. The thermal contact is arranged on the intermediate element on a side of the intermediate element facing away from the reception region. The component carrier is, for example, formed with the aid of one of the methods explained above. The component carrier is, for example, formed in the component carrier assembly and then separated.

An electronic arrangement is provided, which may comprise the component carrier and the electronic component. The component carrier and the electronic element are, for example, fastened on one another and contacted with one another as explained above.

A radiation arrangement is provided, which may comprise the component carrier and the electronic component, wherein the electronic component is a radiation source, for example, as described above.

Methods and/or method steps leading to various examples of the component carrier, the electronic arrangement and/or the radiation arrangement may readily be applied to different examples of the component carrier, the electronic arrangement and/or the radiation arrangement.

Examples are represented in the figures and will be explained in more detail below.

In the following detailed description, reference is made to the appended drawings, which form part of this description and in which specific examples in which our methods and arrangements may be implemented are shown for illustration. In this regard, direction terminology such as “up”, “down”, “forward”, “backward”, “front”, “rear”, and the like is used with reference to the orientation of the figure or figures being described. Since components of examples can be positioned in a number of different orientations, the direction terminology is used for illustration and is in no way restrictive. It is to be understood that other examples may be used and structural or logical modifications may be carried out, without departing from the protective scope of the appended claims. It is to be understood that the features of the various examples described herein may be combined with one another, unless specifically indicated otherwise. The following detailed description is therefore not to be interpreted in a restrictive sense, and the protective scope is defined by the appended claims.

In the scope of this description, terms such as “connected” or “coupled” are used to describe both direct and indirect connection, and direct or indirect coupling. In the figures, identical or similar elements are provided with identical references, insofar as this is expedient.

A light-emitting component may in various examples be formed as a light-emitting diode (LED) or an organic light-emitting diode (OLED) or as an organic light-emitting transistor. The light-emitting component may in various examples be part of an integrated circuit. Furthermore, a multiplicity of light-emitting components may be provided, for example, fitted in a common housing.

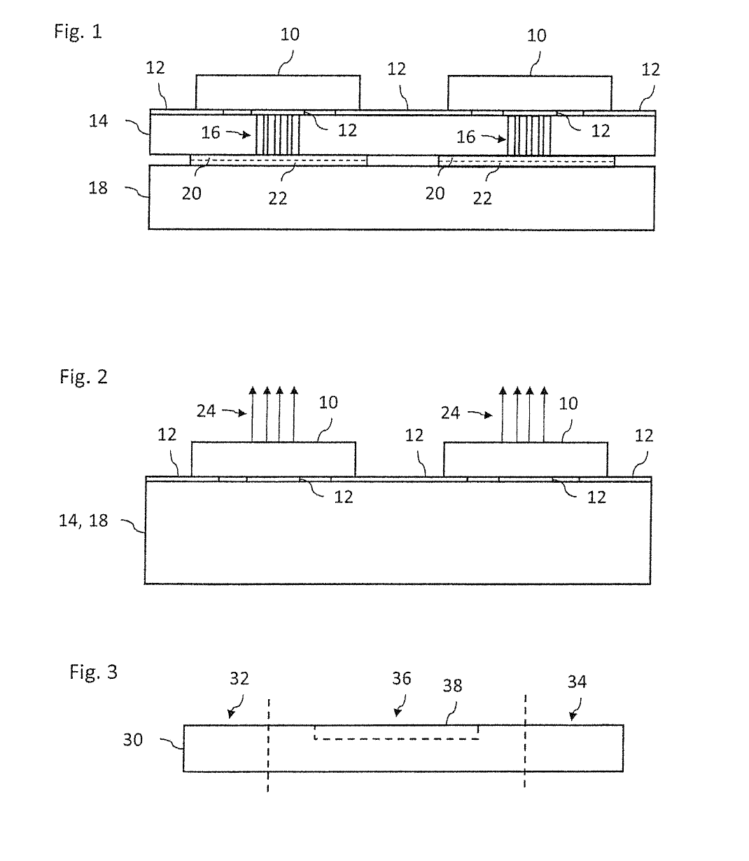

FIG. 1 shows two electronic arrangements 10 arranged on a printed circuit board 14. Alternatively, more or fewer electronic arrangements 10 may also be arranged. A housing of the electronic arrangements 10 may also be referred to as a QFN housing. The electronic arrangements 10 and/or the housing of the electronic arrangements 10 may each have a component carrier, and/or the component carrier may form the housing of the electronic arrangements 10. The electronic arrangement may, for example, be a semiconductor chip and/or, for example, a light-emitting component or a light-absorbing component, for example, a solar cell. The printed circuit board 14 is, for example, an FR4 printed circuit board or an FR5 printed circuit board. Alternatively, the printed circuit board 14 may be a metal-core printed circuit board. The printed circuit board 14 comprises, for example, glass fiber mats embedded in a resin, for example, epoxy resin. For example, the printed circuit board 14 comprises aluminum, copper, Al—SiC and/or AlSi. On its side facing toward the electronic arrangements 10, the printed circuit board 14 comprises electrically conductive first conductor tracks 12. The first conductor tracks 12 comprise, for example, copper or are formed therefrom. The electronic arrangements 10 electrically connect to the first conductor tracks 12 of the printed circuit board 14. For example, the electronic arrangements 10 connect to the first conductor tracks 12 by solder connections. The first conductor tracks 12 are used partially to electrically contact and partially thermally contact the electronic arrangements 10.

Thermal lines 16 extend through the printed circuit board 14. The thermal lines 16 connect via some of the first conductor tracks 12 to the electrical arrangements 10 to dissipate heat from the electronic arrangements 10. The thermal lines 16 comprise, for example, copper or are formed therefrom. The thermal lines 16 are used to dissipate heat rapidly and effectively from the electronic arrangements 10. On its side facing away from the electronic arrangements 10, the printed circuit board 14 comprises electrically conductive second conductor tracks 20. The second conductor tracks 20 comprise copper or are formed therefrom. The conductor tracks 12, 20 comprise, for example, aluminum, copper, nickel, platinum, gold, silver and/or TiW.

The printed circuit board 14 couples thermally and mechanically to a heat sink 18, for example, via the second conductor tracks 20. For example, the printed circuit board 14 may be fixed to the heat sink 18 by a thermally and/or electrically conductive adhesive 22 on the second conductor tracks 20. The heat sink 18 comprises, for example, aluminum, nickel, iron or copper and/or, for example, alloys based on copper, nickel, iron and/or aluminum.

FIG. 2 shows another example in which the electrical arrangements 10 are coupled to the printed circuit board 14 and/or the heat sink 18. For example, the printed circuit board 14 or the heat sink 18 may be formed according to the example shown in FIG. 1. Alternatively, in the example shown in FIG. 2 the printed circuit board 14 may, for example, be omitted and the electronic arrangements 10 may be attached directly to the heat sink 18, or the heat sink 18 may be omitted so that the printed circuit board 14 additionally fulfills the function of a heat sink. In this example, the electronic arrangements 10 are radiation arrangements, which comprise light-emitting components that emit electromagnetic radiation 24. For example, the radiation arrangements emit the electromagnetic radiation 24 in a direction away from the printed circuit board 14 and the heat sink 18, for example, parallel to a surface normal perpendicular to the printed circuit board 14. The electromagnetic radiation 24 is, for example, light, for example, UV light, infrared light and/or light in the visible range.

A plurality of examples of methods of producing a component carrier for the electronic arrangements 10 and/or for the radiation arrangements will be described below.

FIG. 3 shows a preform for a lead frame section 30. The lead frame section 30 is a part of a lead frame (not fully represented) comprising a multiplicity of corresponding lead frame sections 30. The production methods below are explained exclusively with the aid of the one lead frame section 30. The represented states of the lead frame section 30 are representative of corresponding states of the other lead frame sections 30 (not represented) of the lead frame. The lead frame sections 30 may therefore be processed in an assembly in the lead frame. The lead frame, and in particular the lead frame section 30, are used in all production methods explained below as a base element and/or starting element on which all the production methods are based. The lead frame may also be referred to as a QFN lead frame.

The lead frame section 30 comprises, for example, a metal, for example, copper, and/or is formed therefrom. The lead frame section 30 has a high electrical conductivity. Furthermore, the lead frame section 30 has a high thermal conductivity. Furthermore, the lead frame section 30 may optionally be coated. The lead frame section 30 has, for example, a thickness of 10 to 1000 μm, for example, 100 to 500 μm, for example, 150 to 300 μm. The lead frame section 30 is used as a carrier body for one of the component carriers. The lead frame therefore comprises carrier bodies for a plurality of component carriers.

The lead frame section 30 has a first contact section 32 and a second contact section 34. Arranged between the two contact sections 32, 34, there is a reception section 36 which has a reception region 38. The sections 32, 34, 26 and the reception region 38 initially constitute unprocessed sections or regions of the printed circuit board section 30, and are used for illustration of the methods described.

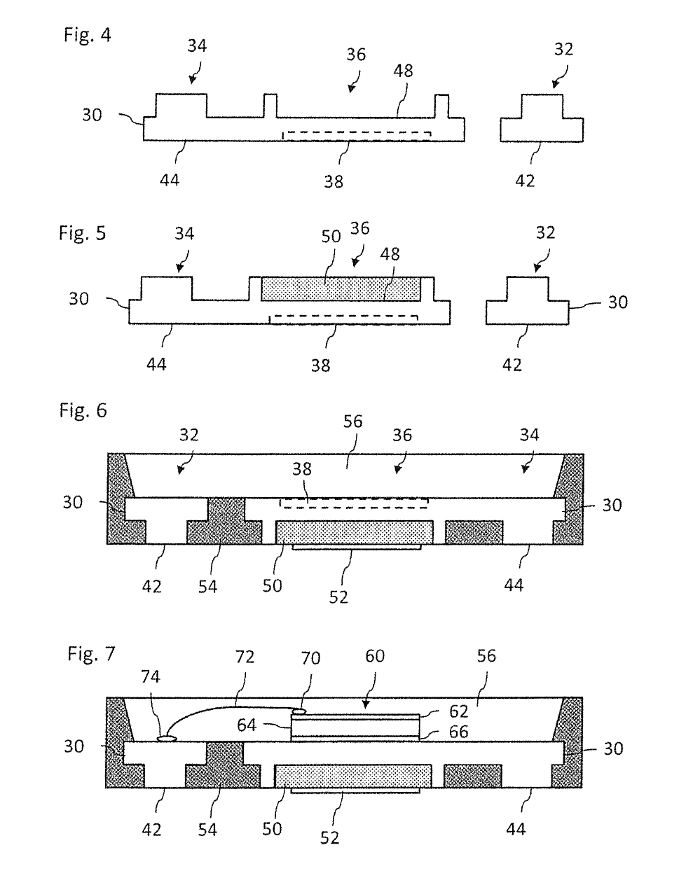

FIGS. 4 to 7 show various successive states of the lead frame section 30 and/or of the corresponding component carrier during a first example of a method of producing the lead frame section 30, or the component carrier.

FIG. 4 shows a first state of the lead frame section 30 during the first example of the method of producing the component carrier. Starting with the preform, shown in FIG. 3, of the lead frame section 30, to achieve the state of the lead frame section 30 as shown in FIG. 4 at least one etching process is carried out. For example, a two-side etching process is carried out in which the preform of the lead frame section 30 is etched from both sides. For example, an etch stop material is applied onto both sides of the lead frame section 30 by a photolithographic method, and the lead frame section 30 is subsequently etched from both sides, for example, in one working step.

During the etching process, the first and the second contact section 32, 34 are separated from one another so that a first contact element 42 is formed in the first contact region 32 and a second contact element 44 is formed in the second contact region 34. The two contact elements 42, 44 are physically separated from one another inside the lead frame section 30 represented, although in the lead frame assembly they may be connected to one another via neighboring lead frame sections 30 (not represented). The second contact element 44 is physically coupled to the reception region 38, and is, for example, formed in one piece with the reception region 38.

Furthermore, during the etching process, an intermediate region 48 which comprises a recess in the lead frame section 30 is formed on an opposite side of the lead frame section 30 from the reception region 38. Furthermore, a further recess may optionally be formed at a transition from the second contact region 34 to the reception region 36, i.e. between the second contact element 44 and the intermediate region 48. The intermediate region 48 and/or the further recess have a depth which corresponds, for example, to half the thickness of the lead frame section 30, in which case the depth may, for example, deviate from half the thickness of the lead frame section 30 by, for example, up to 100 μm, for example, up to 50 μm or, for example, up to 30 μm. As an alternative to formation of the intermediate region 48 in the etching process, the intermediate region 48 may, for example, be formed in the lead frame section 30 by boring, grinding and/or embossing.

FIG. 5 shows a second state of the lead frame section 30 or of the component carrier, during the first example of the method of producing the component carrier in which an intermediate element 50 is introduced into the intermediate region 48. The intermediate element 50 is, for example, a dielectric and/or comprises, for example, an inorganic material. For example, the intermediate element 50 comprises a carrier compound in which particles are embedded. The carrier material comprises, for example, a polymer, for example, epoxy resin, silicone and/or acrylate. The particles comprise, for example, aluminum oxide, quartz, aluminum nitride, boron nitride and/or silicon carbide. The intermediate element 50 is used to electrically insulate the reception region 38 and/or to dissipate heat from the reception region 38. The intermediate element 50 may, for example, be introduced into the intermediate region 48 by dispensing or doctor blading. If necessary, the intermediate element 50 may be dried and/or cured after introduction into the intermediate region 48. For example, the intermediate element 50 may be introduced into the intermediate region 48 in the liquid state and optically and/or thermally cured in the intermediate region. The intermediate element 50 may, for example, have a thickness corresponding to a depth of the intermediate region 48 and/or have a thickness which corresponds to half the thickness of the lead frame section 30.

FIG. 6 shows a third state of the lead frame section 30, or of the component carrier, during the first example of the method of producing the component carrier in which the lead frame section 30 is embedded in a molding material. The lead frame section 30 embedded in the molding material 54 may be referred to as a component carrier. The lead frame embedded in the molding material 54 may be referred to as a component carrier assembly.

The molding material 54 is formed, for example, by molding, for example, transfer molding or by injecting the molding material 54 around the lead frame section. For example, the lead frame comprising all the lead frame sections 30, respectively, with the two contact elements 44, 42 may be placed in a casting or molding body and then cast or injected around with the liquid molding material 54 in which case the molding material 54 may subsequently be dried and/or cured. The casting or molding body is formed such that a reception recess 56 is formed in the molding material 54. In the reception recess 56, at least the reception region 38 is exposed. Furthermore, the first and second contact element 42, 44 may be at least partially exposed in the reception recess 56. Furthermore, the two contact elements 42, 44 are at least partially free of molding material 54 on their sides facing away from the reception recess 56.

As an alternative to introducing the intermediate element 50 into the intermediate region 48 before formation of the molding material 54, during formation of the molding material 54 the intermediate region 48 may be kept free of molding material 54 and the intermediate element 50 may not be introduced until after the formation of the molding material 54 in the intermediate region 48.

Before or after formation of the molding material 54, a thermal contact 52 is formed on a side of the intermediate element 50 facing away from the reception region 38. The thermal contact 52 may, for example, as explained in more detail by way of example below with reference to FIG. 12 and/or 17, be applied flat onto the intermediate element 50 and/or the component carrier, and subsequently structured. Alternatively, the already structured thermal contact 52 may be applied onto the intermediate element 50. The thermal contact 52 is, for example, suitable to enter into a solder connection and may, for example, be wetted with solder. The thermal contact 52 comprises, for example, a metal, for example, copper, silver, nickel, gold or palladium. The thermal contact 52 is used to thermally contact the intermediate element 50. Furthermore, the thermal contact 52 is used to dissipate heat from the intermediate element 50. The thermal contact 52 constitutes a metallization of the intermediate element 50, in particular of a surface of the intermediate element 50. For example, metallization is such that it is solderable, i.e. a solder connection can be produced. The thermal contact 52 may therefore also be used to produce a solder connection.

FIG. 7 shows a fourth state of the component carrier during the first example of the method of producing the component carrier in which an electronic component 60 is applied onto the reception region 38. The component carrier with the electronic component 60 may also be referred to as an electronic arrangement 10 or as an electronic part. The component carrier may be used as a housing for the electronic component. The electronic component 60 is, for example, a semiconductor chip and/or a light-emitting component or a light-absorbing component. The light-emitting component is, for example, an OLED or an LED, for example, a vertically emitting OLED or LED in which a preferential direction of the emitted electromagnetic radiation is perpendicular to the layers of the layer structure of the LED.

The electronic component 60 comprises, for example, a first electrical contact 62 on its side facing away from the lead frame section 30 and a second electrical contact 66 on a side facing toward the lead frame section 30. At least one, for example, a plurality of optical layers are formed between the first electrical contact 62 and the second electrical contact 66. For example, optically functional layers are formed, which, for example, emit light when an electrical voltage is applied between the first and the second electrical contact 62, 66. Furthermore, various scattering and/or conversion layers may be provided as optically functional layers to scatter or convert the electromagnetic radiation generated in the light-emitting component.

The first electrical contact 62 of the electronic component 60 electrically connects via a first bond contact 70, an electrical line 72 and a second bond contact 74 to the first electrical contact element 42 of the component carrier. The second electrical contact 66 is in physical contact with the reception region 38 of the lead frame section 30. The reception region 38 and, therefore, the second electrical contact 66 of the electronic component 60 are electrically coupled to the second contact element 44. The reception region 38 of the lead frame section 30 is therefore used for both mechanical and electrical coupling of the electronic component 60 to the printed circuit board section 30.

During operation of the electronic component 60, heat may be generated, which is absorbed by the lead frame section 30 in the reception region 38. The heat can be dissipated via the intermediate element 50 to the thermal contact 52. At the same time, the intermediate element 50 forms electrical insulation of the reception region 38 from the thermal contact 52, and therefore electrical insulation of the thermal contact 52 from the electronic component 60.

The electronic component 60 is arranged in the reception recess 56 of the molding material 54. The reception recess 56 may in other regards, for example, be filled with a filler material, for example, with a light-scattering material. In other words, the electronic component 60 in the reception recess 56 may be embedded in a filler material.

Subsequently, the lead frame sections 30 may be separated from the lead frame or the component carriers may be separated from the component carrier assembly, for example, by means of cutting or sawing.

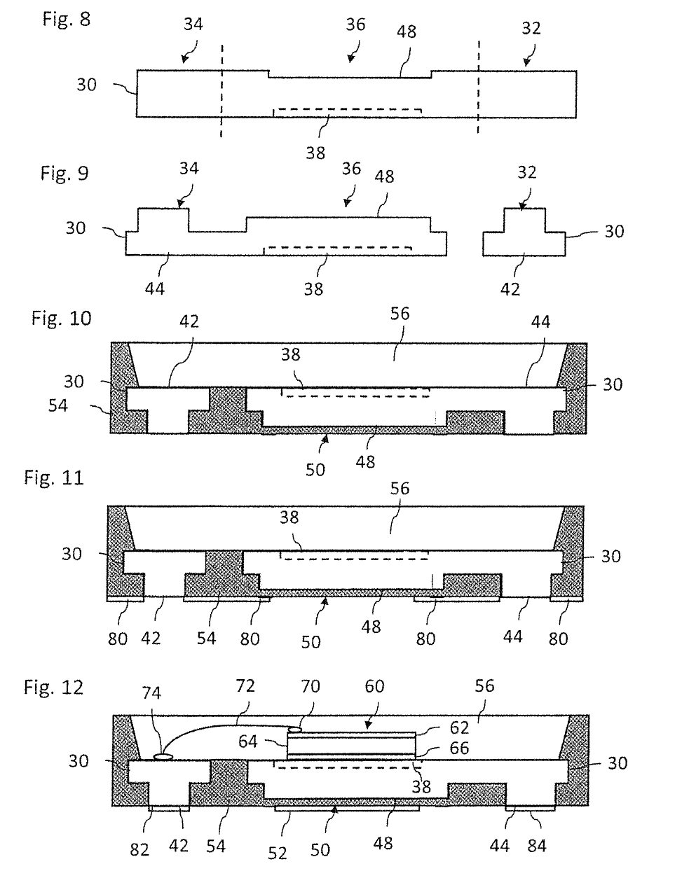

FIGS. 8 to 12 show different states of the lead frame section 30, or of the component carrier, during a second example of the method of producing the component carrier.

FIG. 8 shows a first state of the lead frame section 30 or of the component carrier during the second example of the method of producing the component carrier in which, starting with the lead frame section 30 according to FIG. 3, first only the intermediate region 48 is formed in the reception section 36 on an opposite side of the lead frame section 30 from the reception region 38. For example, the intermediate region 48 may be formed with the aid of an etching process, for example, flat etching in the lead frame section 30. Alternatively, the intermediate region 48 may, for example, be formed by milling, boring, grinding or embossing. A depth of the intermediate region 48 may, for example, be 10 to 100 μm, for example, 20 to 60 μm, for example, 30 to 50 μm, for example, approximately 40 μm.

FIG. 9 shows a second state of the component carrier during the second example of the method of producing the component carrier in which the lead frame section 30 has been subjected to an etching process on both sides, for example, according to the two-side etching process explained with reference to FIG. 4 to produce the contact elements 42, 44. After the two-side etching process, because of the etching process explained with reference to FIG. 8, the lead frame section 30 has a smaller thickness at the reception region 38 and at the intermediate region 48 than in the region of the first and second contact element 42, 44.

FIG. 10 shows a third state of the lead frame section 30 or of the component carrier during the second example of the method of producing the component carrier the lead frame section 30 is embedded in the molding material 54, for example, as explained in more detail with reference to FIG. 6.

Owing to the smaller thickness of the lead frame section 30 at the reception region 38 and the intermediate region 48, the molding material 54 is also formed adjoining the intermediate region 48 so that the intermediate region 48 is covered or filled with molding material 54. The molding material 54 thereby forms the intermediate element 50. In other words, in this example, the intermediate element 50 is formed by the molding material 54. A thickness of the intermediate element 50 corresponds, for example, to approximately a depth of the intermediate region 48 shown in FIG. 8.

FIG. 11 shows a fourth state of the lead frame section 30 or of the component carrier during the second example of the method of producing the component carrier in which an additional layer 80 is applied onto the component carrier on a side of the lead frame section 30 facing away from the reception region 38, specifically such that the two contact elements 42, 44 and the intermediate element 50 remain free of the additional layer 18. The additional layer 80 may also be referred to as a solder mask and/or be used for a lift-off method, or the like.

FIG. 12 shows a fifth state of the lead frame 30 or of the component carrier during the second example of the method of producing the component carrier in which, on a side of the lead frame section 30 facing away from the reception region 38, a first layer contact 82 is formed on the first contact element 42, a second layer contact 84 is formed on the second contact element 44, and the thermal contact 52 is formed on the intermediate element 50. The first layer contact 82, the second layer contact 84 and/or the thermal contact 52 are, for example, applied flat by an electroplating process onto the additional layer 80 and the molded body 54, the additional layer 80 with the layer elements located thereon subsequently being removed from the electroplated layer so that the first layer contact 82, the second layer contact 84 and/or the thermal contact 52 are formed. The layer contacts 82, 84 and/or the thermal contact 52 may alternatively also be applied with the aid of a lift-off method, by a vapor deposition method and/or a sputtering method.

The electronic component 60 is applied onto the lead frame section 30 and contacted on the lead frame section 30, for example, as explained in more detail with reference to FIG. 7.

Subsequently, the lead frame sections 30 can be separated from the lead frame or the component carriers can be separated from the component carrier assembly, for example, by cutting or sawing.

In the second production method, formation of a separate intermediate element 50 may be omitted since this is formed by the molding material 54. In this example of the method of producing a component carrier, the molding material 54 has, for example, a particularly high thermal conductivity.

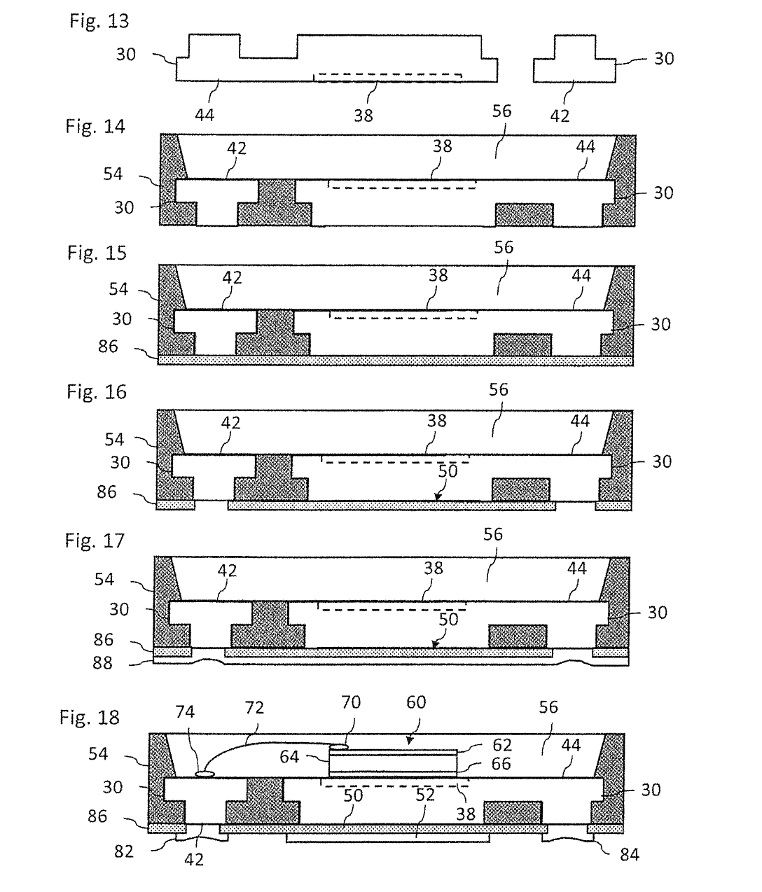

FIGS. 13 to 18 show different states of the lead frame section 30, or of the component carrier, during a third example of the method of producing a component carrier, and/or during a third method of producing the lead frame section 30, or the component carrier.

FIG. 13 shows a first state of the lead frame section 30, or of the component carrier, during the third example of the method of producing the component carrier in which, starting with the state shown in FIG. 3, the lead frame section 30 is initially subjected to a two-side etching process, for example, as explained in more detail with reference to FIG. 4. In contrast to the example shown in FIG. 4, however, an intermediate region 48 is not formed on the opposite side of the lead frame section 30 from the reception region 38.

FIG. 14 shows a second state of the lead frame section 30 or of the component carrier during the third example of the method of producing a component carrier in which the lead frame, in particular the lead frame section 30, is already surrounded by the molding material 54 and/or embedded therein. Formation of the molding material 54 is carried out, for example, according to formation of the molding material 54 as explained in more detail with reference to FIG. 6.

FIG. 15 shows a third state of the lead frame section 30 or of the component carrier during the third example of the method of producing a component carrier in which an intermediate layer 86 is applied on the side of the component carrier facing away from the reception recess 56. The intermediate layer 86 may, for example, be applied flat onto the component carrier, for example, by spin coating, printing, casting or doctor blading and/or by sputtering, thermal deposition and/or lamination in which case the intermediate layer 86 may subsequently be dried or cured if necessary, for example, optically and/or thermally. The intermediate layer 86 comprises the material of the intermediate element 50. The intermediate layer 86 may, for example, be formed to be as thin as possible and/or for example have a thickness of 1 to 50 μm, for example, 20 to 40 μm, for example, approximately 38 μm.

FIG. 16 shows a fourth state of the lead frame section 30 or of the component carrier during the third example of the method of producing the component carrier in which the intermediate layer 86 is structured such that the first contact element 42 and the second contact element 44 are at least partially freed of the intermediate layer 86. In other words, the intermediate layer 86 is structured. The intermediate layer 86 may, for example, be structured by laser ablation, etching and/or mechanically, for example, by milling and/or scratching.

As an alternative to flat application of the intermediate layer 86 as explained with reference to FIG. 15 and the subsequent structuring of the intermediate layer 86 as explained with reference to FIG. 16, the intermediate layer 86 may also be applied in a structured form onto the component carrier, for example, by screen printing or template printing or by a jet printing method (jetting), for example, an inkjet printing method.

FIG. 17 shows a fifth state of the lead frame section 30 or of the component carrier during the third example of the method of producing the component carrier in which a contact layer 88 is formed on a side of the component carrier facing away from the reception region 38. The contact layer 88 extends flat over the intermediate layer 86, the intermediate element 50 and the exposed regions of the first and second contact element 42, 44. The contact layer 88 may, for example, comprise a metal, for example, copper. The contact layer 88 may, for example, have a thickness of 1 to 50 μm, for example, 3 to 10 μm, for example, approximately 5 μm.

FIG. 18 shows a sixth state of the lead frame section 30 or of the component carrier during the third example of the method of producing the component carrier in which the contact layer 88 is structured such that the first layer contact 82, the second layer contact 84 and the thermal contact 52 are formed by it. The contact layer 88 may, for example, be formed and/or structured with the aid of a photolithographic process and an etching process. For example, the structure of the contact layer 88 may be applied on the contact layer 88 with the aid of a photomask.

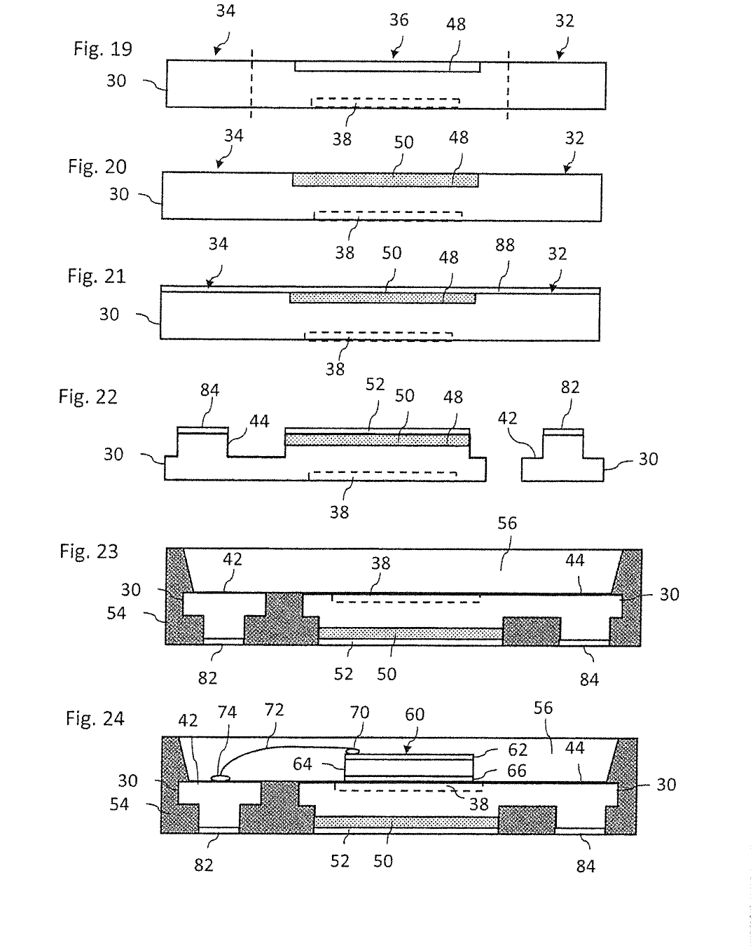

FIGS. 19 to 24 show different states of the lead frame section 30 or of the component carrier during a fourth example of the method of producing the component carrier.

FIG. 19 shows a first state of the lead frame section 30 or of the component carrier during the fourth example of the method of producing the component carrier in which, starting with the lead frame section 30 according to FIG. 3, the intermediate region 48 is formed in the lead frame section 30 on the opposite side of the lead frame section from the reception region 38. The intermediate region 48 is, for example, formed by etching. Furthermore, the intermediate region 48 may, for example, be formed as explained in more detail with reference to FIG. 8. The intermediate region 48 may be formed with a small depth of, for example, 10 to 100 μm, for example, 20 to 50 μm, for example, approximately 40 μm.

FIG. 20 shows a second state of the lead frame section 30 or of the component carrier during the fourth example of the method of producing the component carrier, the intermediate element 50 being introduced into the intermediate region 48. The intermediate element 50 is, for example, introduced into the intermediate region 48 by doctor blading or dispensing. The intermediate element 50 is, for example, introduced into the intermediate region 48 as described in more detail with reference to FIG. 5. The intermediate element 50 may, for example, comprise materials as mentioned in connection with the intermediate element 50 shown in FIG. 5. The material of the intermediate element 50 may, for example, be introduced into the intermediate region 48 in liquid form and/or thermally or optically cured there.

FIG. 21 shows a third state of the lead frame section 30 or of the component carrier during the fourth example of the method of producing a component carrier in which the contact layer 88 is applied flat onto the intermediate element 50 and onto the lead frame section 30 in the first and second contact section 32, 34. The contact layer 88 may, for example, be formed according to the contact layer 88 shown in FIG. 17. The contact layer 88 may, for example, have a thickness of 1 to 10, for example, 5 micrometers.

FIG. 22 shows a fourth state of the lead frame section 30 or of the component carrier, during the fourth example of the method of producing the component carrier before which the lead frame section 30 is subjected with the intermediate element 50 and the contact layer 88 to the two-side etching process, for example, as explained in more detail with reference to FIG. 4. Because of the two-side etching process, the first contact element 42 with the first layer contact 82, the second contact element 44 with the second layer contact 84 and the intermediate element 50 with the thermal contact 52 are formed. Alternatively, the first contact element 42 with the first layer contact 82, the second contact element 44 with the second layer contact 84 and the intermediate element 50 with the thermal contact 52 may also be formed by one-side or two-side mechanical processing, for example, if it is unfavorable to carry out the etching process.

FIG. 23 shows a fifth state of the lead frame section 30 or of the component carrier during the fourth example of the method of producing the component carrier in which the lead frame section 30 is cast or injected around with the molding material 54. Formation of the molding material 54 is carried out, for example, as explained in more detail with reference to FIG. 6. The molding material 54 is formed such that the first layer contact 82, the second layer contact 84 and the thermal contact 52 remain free of molding material.

FIG. 24 shows a sixth state of the lead frame section 30 or of the component carrier during the fourth example of the method of producing the component carrier in which the electronic component 60 is applied onto the reception region 38, and the electronic component 60 is already contacted with the lead frame section 30, for example, as explained in more detail with reference to FIG. 7.

In this example, the intermediate element 50 may be formed to be particularly thin, which can contribute to particularly good dissipation of heat via the intermediate element 50. Furthermore, the component carrier, for example, the housing, for example, the QFN housing is formed flat on its side facing away from the electronic component 60 which can contribute to simple arrangement of the component carrier, for example, on the printed circuit board 14.

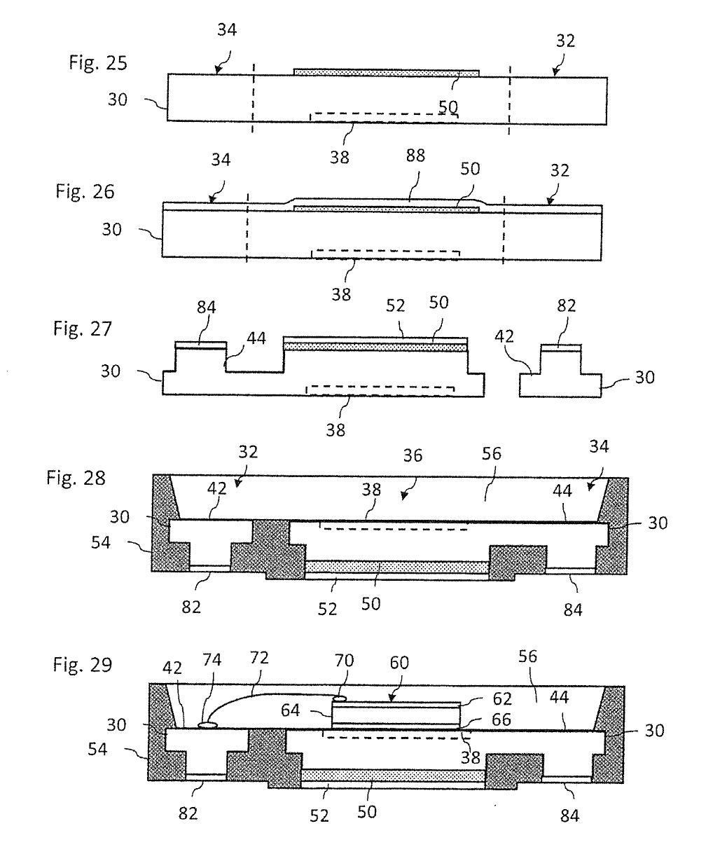

FIGS. 25 to 29 show different states of the component carrier during a fifth example of the method of producing the component carrier.

FIG. 25 shows a first state of the lead frame section 30 or of the component carrier during the fifth example of the method of producing the component carrier in which, on the lead frame section 30 according to FIG. 3, the intermediate element 50 is formed on the side of the lead frame section 30 facing away from the reception region 30. The intermediate element 50 is, for example, applied onto the lead frame section 30 in an already structured form, for example, by template printing, screen printing or by means of an inkjet printing method (jetting). Alternatively, as explained with reference to FIG. 15, the intermediate element 50 may be applied as an intermediate layer 86 and then structured as explained in more detail with reference to FIG. 16 so that the intermediate element 50 is subsequently formed.

FIG. 26 shows a second state of the lead frame section 30 or of the component carrier during the fifth example of the method of producing the component carrier in which the contact layer 88 is applied flat onto the lead frame section 30 and the intermediate element 50, for example, as explained in more detail with reference to FIG. 17.

FIG. 27 shows a third state of the lead frame section 30 or of the component carrier during the fifth example of the method of producing the component carrier, before which the lead frame section 30 is subjected with the contact layer 88 and the intermediate element 50 to the two-side etching process, for example, as explained in more detail with reference to FIG. 4. During the two-side etching process, the first contact element 42 with the first layer contact 82, the second contact element 44 with the second layer contact 84, the intermediate element 50 and the thermal contact 52 are formed. Alternatively, the first contact element 42 with the first layer contact 82, the second contact element 44 with the second layer contact 84, and the intermediate element 50 with the thermal contact 52 may also be formed by one-side or two-side mechanical processing, for example, if it is unfavorable to carry out the etching process. The lead frame section 30 has a larger thickness in the region of the thermal contact 52, of the intermediate element 50 and of the reception region 38 than in the region of the first and/or second contact element 42, 44.

FIG. 28 shows a fourth state of the lead frame section 30 or of the component carrier during the fifth example of the method of producing a component carrier in which the lead frame section 30 is embedded in the molding material 54. The molding material 54 is, for example, formed as explained in more detail with reference to FIG. 6. The molding material 54 comprises the reception recess 56. Furthermore, the molding material 54 is formed such that the first and the second layer contact 82, 84 and the thermal contact 52 are free of molding material 54. On its applied side of the reception region 38, the component carrier has a stepped structure. In particular, the component carrier has a greater thickness in the intermediate section 36 than in the first and second contact section 32, 34. The stepping is represented exaggeratedly large in FIG. 28 for better representation. The stepping may also be configured to be much smaller relative to the dimensions of the component carrier. This may, for example, be achieved by forming the intermediate layer 50 to be as thin as possible.

FIG. 29 shows a fifth state of the lead frame section 30 or of the component carrier during the fifth example of the method of producing the component carrier in which the electronic component 60 is arranged on the component carrier and contacted with the lead frame section 30 of the latter.

The fifth example of the method of producing the component carrier may, for example, be carried out with only one single etching process.

Our methods and arrangements are not restricted to the examples indicated. For example, the molding material 54 may be formed by transfer-compression molding or injection molding in all examples. In principle, for all examples, a small thickness of the intermediate element 50 can contribute to good dissipation of heat. The small thickness of the intermediate element 50 may, for example, be achieved by a small depth of the recess of the intermediate region 48 or by a small thickness of the intermediate layer 86.

1.-16. (canceled)

17. A method of producing a component carrier for an electronic component comprising:
a lead frame section comprising an electrically conductive material, the lead frame section having a first contact section that forms a first electrical contact element, a second contact section that forms a second electrical contact element, and a reception region that receives the electronic component, at least the reception region and the second contact section being electrically conductively connected to one another,
a thermally conductive and electrically insulating intermediate element that dissipates heat from the reception region and electrically insulates the reception region formed at least on an opposite side of the lead frame section from the reception region, and
a thermal contact that thermally contacts the electronic component formed at least on a side of the intermediate element facing away from the reception region.

18. The method as claimed in claim 17, wherein the thermal contact comprises a metal.

19. The method as claimed in claim 17, wherein the first contact element and the second contact element are formed from the lead frame section, the first contact element being physically separated from the second contact element.

20. The method as claimed in claim 19, wherein the first contact element is physically separated from the second contact element with the aid of an etching process.

21. The method as claimed in claim 19, wherein an intermediate region that receives the intermediate element is formed on the opposite side of the lead frame section from the reception region.

22. The method as claimed in claim 21, wherein the intermediate region is formed in the same working step as the first and the second contact element.

23. The method as claimed in claim 19, wherein the intermediate element and/or the thermal contact are formed in the same working step as the first and the second contact element.

24. The method as claimed in claim 19, wherein the first and the second contact element are at least partially embedded in a molding material.

25. The method as claimed in claim 24, wherein the molding material is used as the intermediate element.

26. The method as claimed in claim 24, wherein the molding material is shaped such that it has a reception recess in which the first contact element, the second contact element and/or the reception region are at least partially exposed.

27. A method of producing an electronic arrangement comprising:
producing a component carrier according to the method of claim 17,
applying the electronic component onto the reception region,
contacting a first electrical contact of the electronic component with the first contact element, and
contacting a second electrical contact of the electronic component with the second contact element.

28. The method as claimed in claim 27, wherein a radiation source is used as the electronic component.

29. A method of producing a component carrier for an electronic component comprising:
providing a lead frame section which comprises an electrically conductive material, the lead frame section having a first contact section that forms a first electrical contact element, a second contact section that forms a second electrical contact element, and a reception region that receives the electronic component, at least the reception region and the second contact section electrically conductively connected to one another,
forming the first contact element and the second contact element from the lead frame section, the first contact element being physically separated from the second contact element,
forming a thermally conductive and electrically insulating intermediate element that dissipates heat from the reception region and electrically insulates the reception region at least on an opposite side of the lead frame section from the reception region,
embedding the first and the second contact element at least partially in a molding material, and
forming a thermal contact that thermally contacts the electronic component at least on a side of the intermediate element facing away from the reception region.

30. A component carrier that receives and contacts an electronic component comprising:
a lead frame section having a first contact element that contacts a first electrode of the electronic component, having a second contact element that contacts a second electrode of the electronic component, and having a reception region that receives the electronic component, the reception region and the second contact element electrically conductively connected to one another,
an intermediate element that electrically insulates the reception region and arranged on an opposite side of the lead frame section from the reception region,
a thermal contact that thermally contacts the electronic component, the thermal contact being arranged on the intermediate element on a side of the intermediate element facing away from the reception region.

31. An electronic arrangement comprising the component carrier as claimed in claim 30 and the electronic component.

32. A radiation arrangement comprising the component carrier as claimed in claim 30 and the electronic component, wherein the electronic component is a radiation source.
